(19) United States
(12) Patent Application Publication
(10) Pub. No.: US 2025/0311526 A1
(43) Pub. Date: Oct. 2, 2025

(54) SOLAR CELL AND METHOD FOR MANUFACTURING SAME

(71) Applicant: Jiangsu Huixian Display Technology Co., Ltd., Kunshan (CN)

(72) Inventors: Kui LV, Kunshan (CN); Shengzhi DONG, Kunshan (CN); Rubo XING, Kunshan (CN)

(73) Assignee: Jiangsu Huixian Display Technology Co., Ltd., Kunshan (CN)

(21) Appl. No.: 19/239,840

(22) Filed: Jun. 16, 2025

(30) Foreign Application Priority Data
Jun. 17, 2024 (CN) 202410773584.X

(51) Int. Cl. H10K 39/38; H10K 71/60; H10K 85/50

(52) U.S. Cl. CPC H10K 39/38; H10K 71/60; H10K 85/50

(57) ABSTRACT

The present application provides a solar cell and a method for manufacturing same. The solar cell includes a substrate, cell units, connecting layers, and a bus component. The cell units are located on one side of the substrate. Each cell unit includes a first electrode layer, an optical conversion layer and a second electrode layer which are stacked in sequence, the second electrode layer including a first sub-portion and a second sub-portion. Each connecting layer is located on a side of the cell unit facing away from the substrate. The bus component is electrically connected to the connecting layers.

### CROSS-REFERENCE TO RELATED APPLICATIONS

The present application claims priority to Chinese Patent Application No. 202410773584.X, entitled “SOLAR CELL AND METHOD FOR MANUFACTURING SAME” and filed on Jun. 17, 2024, which is incorporated herein by reference in its entirety.

### FIELD

The present application relates to the field of solar cells, and in particular to a solar cell and a method for manufacturing same.

### BACKGROUND

In recent years, perovskite photovoltaic solar cells have developed rapidly. The highest photoelectric conversion efficiency of small-area perovskite photovoltaic solar cells has reached 25.7%, and has a theoretical upper limit exceeding that of traditional crystalline silicon cells. The perovskite photovoltaic solar cells are expected to replace crystalline silicon cells in the future.

In the development of perovskite photovoltaic solar cells, how to improve the photoelectric conversion efficiency of perovskite photovoltaic solar cells has always been a research direction in the perovskite photovoltaic solar cell technology.

### SUMMARY

Embodiments of the present application provide a solar cell and a method for manufacturing same, which can improve the photoelectric conversion efficiency.

One embodiment of the present application provides a solar cell, which includes a substrate, cell units, connecting layers, and a bus component. The cell units are located on one side of the substrate. Each of the cell units includes a first electrode layer, an optical conversion layer and a second electrode layer which are stacked in sequence, the second electrode layer including a first sub-portion and a second sub-portion, the first sub-portion being insulated from the first electrode layer, and the second sub-portion being electrically connected to the first electrode layer. Each connecting layer is located on a side of the cell unit facing away from the substrate, and includes a first connecting line and a second connecting line, the first connecting line being electrically connected to the first sub-portion, and the second connecting line being electrically connected to the second sub-portion. The bus component is electrically connected to the connecting layers.

In some embodiments, the plurality of cell units are arranged side by side in a first direction, and the first connecting line and the second connecting line are arranged at two ends of each of the cell units in the first direction.

In some embodiments, the first sub-portion and the second sub-portion are spaced apart from each other in the first direction.

In some embodiments, each of the cell units includes a first groove running through the second electrode layer.

In some embodiments, each of the cell units includes a first groove running through the second electrode layer and at least part of the optical conversion layer.

In some embodiments, a gap is provided between two adjacent cell units, and the first connecting line of one of the two adjacent cell units and the second connecting line of the other are arranged close to the gap.

In some embodiments, each of the cell units further includes a via running through the optical conversion layer, at least part of the second sub-portion being located in the via.

In some embodiments, the second sub-portion includes a main body portion and a connecting portion, the main body portion and the first sub-portion being arranged on a same layer, the connecting portion being connected to the first electrode layer through the via, a second groove being formed in a side of the connecting portion facing away from an inner wall of the via, and part of the second connecting line being located in the second groove.

In some embodiments, the second connecting line includes a covering portion and an extension portion connected to each other, the covering portion covering at least part of a side of the main body portion facing away from the first electrode layer, and the extension portion extending from a side of the covering portion facing the first electrode layer into the second groove.

In some embodiments, the optical conversion layer includes a first charge transport layer, a semiconductor layer and a second charge transport layer which are stacked in sequence in a direction away from the substrate, and a projection of the extension portion in the first direction at least partially overlaps with a projection of the semiconductor layer in the first direction.

In some embodiments, a material of the semiconductor layer includes one or a combination of crystalline silicon, perovskite, arsenic telluride, copper indium gallium selenide and gallium arsenide.

In some embodiments, the plurality of cell units are arranged side by side in the first direction, the bus component is arranged on at least one side of the cell units in a second direction, and the plurality of cell units are arranged in parallel with the bus component by the connecting layers, the first direction intersecting with the second direction.

In some embodiments, the bus component includes a first bus line and a second bus line which are respectively arranged on two sides of the cell unit in the second direction. The first connecting lines of the plurality of cell units are connected to the first bus line, and the second connecting lines of the plurality of cell units are connected to the second bus line.

One embodiment of the present application provides a method for manufacturing a solar cell. The method includes: sequentially forming a first conductive layer and an optical prefabrication layer on the substrate; patterning the optical prefabrication layer to expose part of the first conductive layer; sequentially forming a second conductive layer and a third conductive layer on a side of the optical prefabrication layer facing away from the first conductive layer, with part of the second conductive layer being electrically connected to the first conductive layer; and patterning the first conductive layer, the optical prefabrication layer, the second conductive layer and the third conductive layer so that the first conductive layer, the optical prefabrication layer, the second conductive layer and the third conductive layer are separated to form a plurality of cell units spaced apart from each other, wherein the first conductive layer forms a plurality of first electrode layers, the optical prefabrication layer forms a plurality of optical conversion layers, the second conductive layer forms a plurality of first sub-portions and a plurality of second sub-portions, and the third conductive layer forms a plurality of first connecting lines and a plurality of second connecting lines.

In some embodiments, the step of sequentially forming a second conductive layer and a third conductive layer on a side of the optical prefabrication layer facing away from the first conductive layer includes: forming a plurality of conductive portions spaced apart from each other on a side of the second conductive layer facing away from the optical prefabrication layer. The step of patterning the first conductive layer, the optical prefabrication layer, the second conductive layer and the third conductive layer includes: patterning the conductive portions so that part of each of the conductive portions forms the first connecting line and the other part forms the second connecting line, the first connecting line and the second connecting line being connected to different cell units.

The embodiments of the present application provide a solar cell and a method for manufacturing same. The solar cell includes a substrate, cell units, connecting layers, and a bus component. A second electrode layer in each cell unit includes a first sub-portion and a second sub-portion, with a voltage being formed between the first sub-portion and the first electrode layer. With the second sub-portion, the connecting line between the first electrode layer and the outside can be transferred to the side of the same layer as the first sub-portion, and the current formed by the first sub-portion and the first electrode layer is extracted by means of the first connecting line and the second connecting line. Photogenerated carriers in each cell unit are transferred from the optical conversion layer to the connecting layer, and then from the connecting layer to the bus component, which reduces the loss of photogenerated current due to the internal resistance of the cell unit, thereby improving the photoelectric conversion efficiency.

### BRIEF DESCRIPTION OF THE DRAWINGS

In order to describe the embodiments of the present application more clearly, the accompanying drawings required for the embodiments of the present application are briefly described below.

FIG. 1 is a structural schematic top view of a solar cell according to an embodiment of the present application;

FIG. 2 is a structural schematic cross-sectional view along line A-A in FIG. 1;

FIG. 3 is a structural schematic enlarged view of part P in FIG. 2;

FIG. 4 is another structural schematic enlarged view of part P in FIG. 2;

FIG. 5 is a structural schematic cross-sectional view of a cell unit according to an embodiment of the present application;

FIG. 6 is a flowchart of a method for manufacturing a solar cell according to an embodiment of the present application; and

FIGS. 7 to 10 are structural schematic diagrams of a process of a method for manufacturing a solar cell according to an embodiment of the present application.

### LIST OF REFERENCE SIGNS

10. a substrate;
20. cell unit; 21. first electrode layer; 22. optical conversion layer; 221. first charge transport layer; 222. semiconductor layer; 223. second charge transport layer; 23. second electrode layer; 231. first sub-portion; 232. second sub-portion; 232a. main body portion; 232b. connecting portion;
30. connecting layer; 31. first connecting line; 32. second connecting line; 321. covering portion; 322. extension portion;
40. bus component; 41. first bus line; 42. second bus line;
H1. first groove; H2. second groove; H3. via; H4. gap;
50. first conductive layer; 60. optical prefabrication layer; 70. second conductive layer; 80. third conductive layer; 81. conductive portion;
X. first direction; Y. second direction; Z. thickness direction.

### DETAILED DESCRIPTION OF THE EMBODIMENTS

Features and exemplary embodiments of the present application will be described in detail below. In order to make the embodiments of the present application clearer, the present application will be further described in detail below with reference to the accompanying drawings and specific embodiments. It should be understood that the specific embodiments described herein are merely intended to explain the present application and are not intended to limit the present application. The present application may be implemented without some of these specific details. The following description of the embodiments is merely to provide a better understanding of the present application by illustrating examples of the present application.

It should be noted that, herein, relative terms such as “first” and “second” are only used to distinguish one entity or operation from another entity or operation, and do not necessarily require or imply that such an actual relationship or order exists between these entities or operations. Moreover, the terms “include”, “comprise”, or any other variants thereof are intended to cover a non-exclusive inclusion, so that a process, a method, an article, or a device that includes a list of elements not only includes those elements but also includes other elements that are not listed, or further includes elements inherent to such a process, method, article, or device. If no more limitations are made, an element limited by “including . . . ” does not exclude other identical elements existing in the process, the method, the article, or the device which includes the element.

With the development of photovoltaic cell technology, thin-film photovoltaic cells have become a new type of photovoltaic device to alleviate the energy crisis. Thin-film solar cells are flexible and can be made into non-planar structures, which makes the thin-film solar cells have a wide range of applications. The thin-film solar cells can be combined with a building or become a part of the building, have been applied in flexible products such as vehicle-mounted photovoltaic devices and wearable electronic devices, and have broad application prospects. Thin-film solar cells prepared based on organic-inorganic hybrid metal halide (perovskite) materials have received great attention in the field of photovoltaic solar cells in recent years. In just over a decade, the photoelectric conversion efficiency of single perovskite solar cells (PSCs) has increased from 3.8% to 25.7%, approaching that of monocrystalline silicon solar cells. During the manufacturing process for thin-film solar cells, a plurality of solar cells are connected in series, which reduces the output current, increases the output voltage, and reduces the loss of output power due to internal resistance, thereby increasing the external output power. However, the series process is relatively complicated, requiring high precision during the manufacturing process, and the internal resistance of the series connection is relatively large, which still causes loss of output power, limiting the improvement of the photoelectric conversion efficiency of perovskite solar cells.

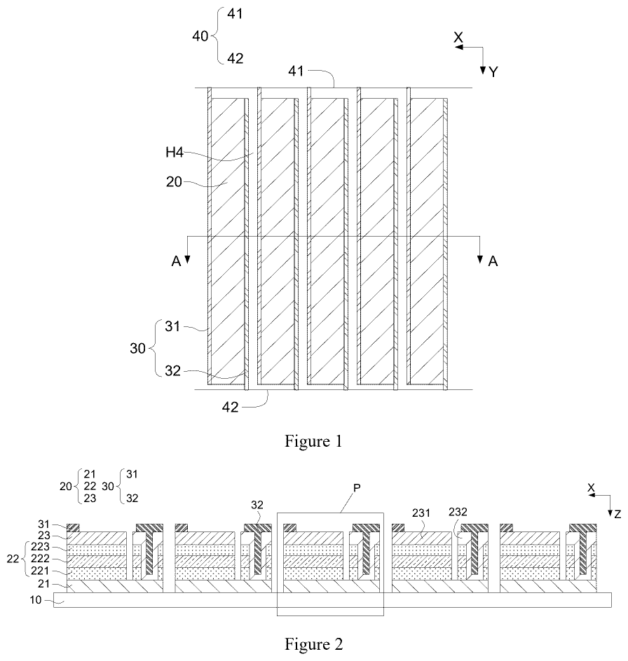

FIG. 1 is a structural schematic top view of a solar cell according to an embodiment of the present application. FIG. 2 is a structural schematic cross-sectional view along line A-A in FIG. 1.

In view of this, in one embodiment, referring to FIGS. 1 and 2, an embodiment of the present application provides a solar cell, which includes a substrate 10, cell units 20, connecting layers 30, and a bus component 40. The cell units 20 are located on one side of the substrate 10. Each cell unit 20 includes a first electrode layer 21, an optical conversion layer 22 and a second electrode layer 23 which are stacked in sequence. The second electrode layer 23 includes a first sub-portion 231 and a second sub-portion 232, the first sub-portion 231 being insulated from the first electrode layer 21, and the second sub-portion 232 being electrically connected to the first electrode layer 21. Each connecting layer 30 is located on a side of the cell unit 20 facing away from the substrate 10. The connecting layer 30 includes a first connecting line 31 and a second connecting line 32, the first connecting line 31 being electrically connected to the first sub-portion 231, and the second connecting line 32 being electrically connected to the second sub-portion 232. The bus component 40 is electrically connected to the connecting layers 30.

For example, the substrate 10 may be a substrate 10 made of glass or another light-transmitting material, and light rays from a side of the substrate 10 facing away from the cell units 20 may pass through the substrate 10 and irradiate the first electrode layers 21.

Specifically, a solar cell includes a plurality of cell units 20. The plurality of cell units 20 may be arranged side by side in a single direction or in an array in various directions. The cell unit 20 is the smallest unit achieving the function of a solar cell capable of extracting electric power. The cell unit 20 has one or more pairs of electrodes that output electric power.

For example, the first electrode layer 21 may be a transparent conductive oxide (TCO) electrode. The material of the second electrode layer 23 includes a conductive metal such as Au or Ag, and may also be a TCO electrode, such as indium tin oxide (ITO) or fluorine-doped tin oxide (FTO), or a carbon electrode.

For example, the material of the optical conversion layer 22 includes a photogenerated carrier forming material. Photogenerated carriers refer to electron-hole pairs which are generated, during light irradiation on a semiconductor, when electrons in the valence band absorb photons and enter the conduction band in the case of the energy of the photons being equal to or greater than the bandgap width of the semiconductor. This type of carrier is called photogenerated carrier.

In one embodiment, the first electrode layer 21 is located between the second electrode layer 23 and the substrate 10. Of course, the second electrode layer 23 may also be located between the first electrode layer 21 and the substrate 10.

The second electrode layer 23 includes a first sub-portion 231 and a second sub-portion 232. The first sub-portion 231, the second sub-portion 232 and the first electrode layer 21 may be disposed opposite each other in a thickness direction Z of the substrate 10. In one embodiment, a projection of the first sub-portion 231 in the thickness direction Z falls within a projection of the first electrode layer 21 in the thickness direction Z. In one embodiment, a projection of the second sub-portion 232 in the thickness direction Z falls within the projection of the first electrode layer 21 in the thickness direction Z.

It can be understood that at least part of the first sub-portion 231 and at least part of the second sub-portion 232 are located on a side of the optical conversion layer 22 facing away from the first electrode 21. The second sub-portion 232 can serve as a connection structure of the first electrode layer 21 to transfer the connection of the first electrode layer 21 from a side of the optical conversion layer 22 facing the first electrode layer 21 to the side of the optical conversion layer 22 facing away from the first electrode layer 21 so that the first connecting line 31 and the second connecting line 32 are both located on the side of the second electrode layer 23 facing away from the first electrode layer 21, thereby simplifying the difficulty of connecting the first connecting line 31 and the second connecting line 32 to the bus component 40.

In one embodiment, the projection of the first connecting line 31 in the thickness direction Z may be located within the projection of the first sub-portion 231 in the thickness direction Z, so as to reduce the redundant arrangement of the first connecting line 31, thereby reducing the manufacturing cost of the first connecting line 31. When the first sub-portion 231 is a transparent electrode, the influence of the first connecting line 31 on the effective area of the cell can also be reduced.

In one embodiment, the projection of the second connecting line 32 in the thickness direction Z can be located within the projection of the second sub-portion 232 in the thickness direction Z, so that the possibility of a short circuit between the second connecting line 32 and the first sub-portion 231 is reduced, and the area of the second sub-portion 231 occupied by the second connecting line 32 is reduced, so as to reduce the area of the second sub-portion 231 in the cell unit 20, reduce the overall area of the dead zone, and increase the proportion of the effective area in the cell unit 20, thereby improving the optical conversion efficiency.

For example, the plurality of cell units 20 are disposed side by side in the first direction X, and the cell units 20 are disposed extending in a second direction Y, and the first connecting line 31 and the second connecting line 32 may both be disposed extending in the second direction Y.

For example, the solar cell includes one or more of solar cells of different structures, such as silicon solar cells, arsenic telluride, copper indium gallium selenide and other semiconductor solar cells, perovskite solar cells, and organic solar cells.

The embodiments of the present application provide a solar cell, which includes a substrate 10, cell units 20, connecting layers 30 and a bus component 40. A second electrode layer 23 in each cell unit 20 includes a first sub-portion 231 and a second sub-portion 232, with a voltage being formed between the first sub-portion 231 and the first electrode layer 21. With the second sub-portion 232, the connecting line between the first electrode layer 21 and the outside can be transferred to the side of the same layer as the first sub-portion 231, and the current formed by the first sub-portion 231 and the first electrode layer 21 is extracted by means of the first connecting line 31 and the second connecting line 32. Photogenerated carriers in each cell unit 20 are transferred from the optical conversion layer 22 to the connecting layer 30, and then transferred from the connecting layer 30 to the bus component 40, which reduces the loss of photogenerated current due to the internal resistance of the cell unit 20, especially the large-area electrode, thereby improving the photoelectric conversion efficiency.

In some optional embodiments, as shown in FIGS. 1 and 2, a plurality of cell units 20 are arranged side by side in a first direction X, and a first connecting line 31 and a second connecting line 32 are arranged at two ends of the cell unit 20 in the first direction X.

In one embodiment, the cell units 20 are arranged extending in a second direction Y, and the plurality of cell units 20 are arranged side by side in the first direction X. The first connecting line 31 in a single cell unit 20 may be arranged adjacent to the first connecting line 31 or the second connecting line 32 in the adjacent cell unit 20. In one embodiment, the first connecting line 31 and the second connecting line 32 are both arranged extending in the second direction Y.

In these optional embodiments, the above configuration can reduce the possibility of a short circuit between the first connecting line 31 and the second connecting line 32, and reduce the difficulty of manufacturing the first connecting line 31 and the second connecting line 32. In addition, the first connecting line 31 and the second connecting line 32 are separately arranged at two ends, which can also reduce the influence of the first connecting line 31 and the second connecting line 32 on the effective area of the cell unit 20, thereby improving the optical conversion efficiency of the cell unit.

In some optional embodiments, as shown in FIGS. 1 and 2, the first sub-portion 231 and the second sub-portion 232 are spaced apart in the first direction X, which reduces the possibility of a short circuit between the first sub-portion 231 and the second sub-portion 232 and in turn reduces the possibility of a short circuit between the first sub-portion 231 and the first electrode layer 21, thereby improving the reliability of the solar cell.

In one embodiment, an insulating material may be provided between the first sub-portion 231 and the second sub-portion 232. Of course, a gap H4 may also be provided between the first sub-portion 231 and the second sub-portion 232. In one embodiment, the insulating material includes polyolyaltha olfin (POE) or ethylene vinyl acetate copolymer (EVA).

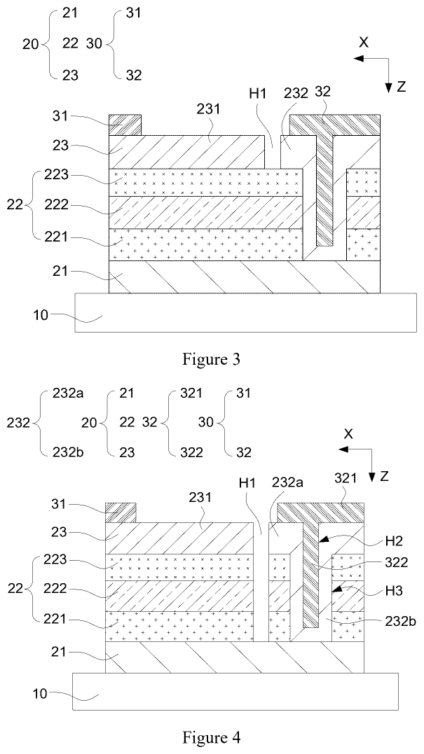

FIG. 3 is a structural schematic enlarged view of part P in FIG. 2.

In some optional embodiments, as shown in FIG. 3, the cell unit 20 includes a first groove H1, the first groove H1 running through the second electrode layer 23.

Specifically, the first groove H1 runs through the second electrode layer 23 to separate the second electrode layer 23 into two parts, one part forming a first sub-portion 231 and the other part forming a second sub-portion 232, the area of the first sub-portion 231 being greater than the area of the second sub-portion 232. Of course, in some other examples, the second groove H2 may also equally divide the second electrode layer 23.

In these optional embodiments, the first groove H1 is provided to enable the second electrode layer 23 to be divided into two parts so that the connection between the first electrode layer 21 and the second connecting line 32 can be achieved by the second sub-portion 232, which reduces the manufacturing steps of the solar cell, thereby improving the manufacturing efficiency of the solar cell.

In some optional embodiments, as shown in FIG. 4, the cell unit 20 includes a first groove H1. The first groove H1 runs through the second electrode layer 23 and at least part of the optical conversion layer 22, which reduces the manufacturing accuracy of the first groove H1, thereby reducing the process difficulty while reducing the insulation short circuit between the first sub-portion 231 and the second sub-portion 232.

In one embodiment, the optical conversion layer 22 may include a multi-layer structure, and the first groove H1 may run through one or more layers of the multi-layer structure.

In some optional embodiments, as shown in FIGS. 1 and 2, a gap H4 is provided between two adjacent cell units 20, and the first connecting line 31 of one of the two adjacent cell units 20 and the second connecting line 32 of the other are arranged close to the gap H4.

For example, two adjacent cell units 20 are arranged side by side in the first direction X. As shown, in the two adjacent cell units 20 in the direction from the left side to the right side of the figure, the first cell unit 20 has the first connecting line 31 and the second connecting line 32, and the second cell unit 20 has the first connecting line 31 and the second connecting line 32. Moreover, the second connecting line 32 in the first cell unit 20 is close to the gap H4 between the two cell units 20, and the first connecting line 31 in the second cell unit 20 is close to the gap H4 between the two cell units 20.

In the embodiments of the present application, the above configuration reduces the possibility of a short circuit between the first connecting line 31 and the second connecting line 32 in a single cell unit 20 so that the adjacent first connecting line 31 and second connecting line 32 in two adjacent cell units 20 can be formed through one patterning process during the preparation of the connecting layer 30, so as to reduce the production process of the solar cell, thereby improving the production efficiency of the solar cell.

FIG. 4 is another structural schematic enlarged view of part P in FIG. 2.

In some optional embodiments, as shown in FIG. 4, the cell unit 20 further includes a via H3 running through the optical conversion layer 22, and at least part of the second sub-portion 232 is located in the via H3.

For example, the via H3 exposes part of the first electrode layer 21, and the entire second sub-portion 232 may be located in the via H3, for example, a side of the second sub-portion 232 facing away from the first electrode layer 21 is flush with a side of the first sub-portion 231 facing away from the first electrode layer 21. In one embodiment, part of the second sub-portion 232 is located in the via H3, and the other part thereof covers a side of the optical conversion layer 22 facing away from the first electrode layer 21.

In these optional embodiments, the above configuration is conducive to reducing the difficulty of connecting the second sub-portion 232 and the first electrode layer 21 to improve the connection reliability between the second connecting line 32 and the first electrode layer 21.

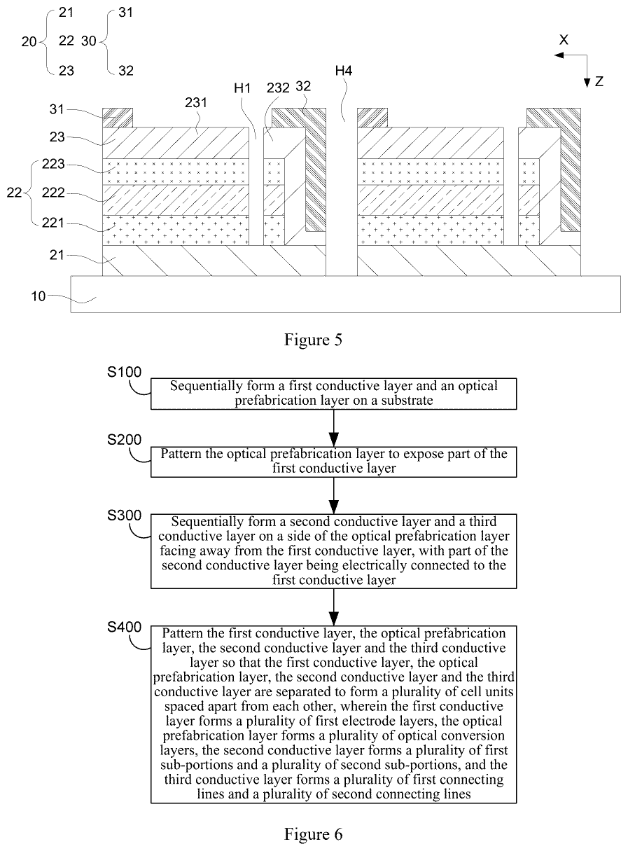

FIG. 5 is a structural schematic cross-sectional view of a cell unit according to an embodiment of the present application.

In some other examples, as shown in FIG. 5, a gap H4 is provided between a cell unit 20 and a cell unit 20, and a second sub-portion 232 extends along an inner wall of the gap H4 and is electrically connected to a first electrode layer 21.

In some optional embodiments, as shown in FIG. 4, the second sub-portion 232 includes a main body portion 232a and a connecting portion 232b. The main body portion 232a and the first sub-portion 231 are arranged on the same layer. The connecting portion 232b is connected to the first electrode layer 21 through a via H3. A second groove H2 is formed on a side of the connecting portion 232b facing away from an inner wall of the via H3, and at least part of the second connecting line 32 is located in the second groove H2.

For example, the main body portion 232a and the first sub-portion 231 are both located on a side of the optical conversion layer 22 facing away from the first electrode layer 21, and the connecting portion 232b is connected to the main body portion 232a. The connecting portion 232b can cover the side wall of the via H3 and a surface of the first electrode layer 21 exposed from the via H3. During the manufacturing process of the second electrode layer 23, the film thickness of the second electrode layer 23 may be less than half of the inner diameter of the via H3 so that after the connecting portion 232b is formed, a second groove H2 is formed on a side of the connecting portion 232b facing away from the inner wall of the via H3, and at least part of the second connecting line 32 may be arranged in the second groove H2, so as to reduce the positioning accuracy of the second connecting line 32 during the manufacturing process to reduce the difficulty of manufacturing the second connecting line 32. In one embodiment, after the second electrode layer 23 is formed, the via H3 is filled with the connecting portion 232b, and patterning is performed from the surface of the connecting portion 232b facing away from the first electrode layer 21 toward the inside of the connecting portion 232b, so as to form the second groove H2.

In some optional embodiments, as shown in FIG. 4, the second connecting line 32 includes a covering portion 321 and an extension portion 322 connected to each other. The covering portion 321 covers at least part of a side of the main body portion 232a facing away from the first electrode layer 21, and the extension portion 322 extends from a side of the covering portion 321 facing the first electrode layer 21 into the second groove H2.

In one embodiment, a projection of the covering portion 321 in a thickness direction Z may be located within a projection of the main body portion 232a in the thickness direction Z.

In one embodiment, the covering portion 321 and the first connecting line 31 are both located on a side of the second electrode layer 23 facing away from the first electrode layer 21.

In one embodiment, one end of the extension portion 322 is connected to the covering portion 321, and the other end extends into the second groove H2 and may be connected to the bottom wall of the second groove H2.

In these optional embodiments, providing the covering portion 321 is conducive to simplifying the difficulty of connecting the second connecting line 32 to the bus component 40; and providing the extension portion 322 is conducive to increasing the contact area of the second connecting line 32 and the cell unit 20, so as to reduce the resistance of the second connecting line 32 and the cell unit 20, thereby improving the photoelectric conversion efficiency of the solar cell.

In some optional embodiments, as shown in FIG. 4, the optical conversion layer 22 includes a first charge transport layer 221, a semiconductor layer 222 and a second charge transport layer 223 which are stacked in sequence in a direction away from the substrate 10, and a projection of the extension portion 322 in the first direction X at least partially overlaps with a projection of the semiconductor layer 222 in the first direction X.

For example, the stacked structure of the cell unit 20 sequentially includes the first electrode layer 21, the first charge transport layer 221, the semiconductor layer 222, the second charge transport layer 223 and the second electrode layer 23.

In one embodiment, an interface modification layer or other functional film layer may be provided between the electron transport layer and the semiconductor layer 222.

For example, a projection of the semiconductor layer 222 in the first direction X may fall within a projection of the extension portion 322 in the first direction X. In one embodiment, the projection of the semiconductor layer 222 in the first direction X partially overlaps with a projection of the extension portion 322 in the first direction X. In these optional embodiments, the above configuration is conducive to shortening the path of transfer of photogenerated carriers in the optical conversion layer 22 to the second connecting line 32, which in turn reduces the internal resistance of the cell unit 20, thereby improving the photoelectric conversion efficiency of the solar cell.

In some optional embodiments, a material of the semiconductor layer includes one or a combination of crystalline silicon, perovskite, arsenic telluride, copper indium gallium selenide and gallium arsenide. In some examples, the material of the semiconductor layer may include one or a combination of organic materials and inorganic materials. For example, organic materials and inorganic materials are added to the perovskite material. In some examples, the material of the semiconductor layer may include one or a combination of organic components and inorganic components, for example, organic-inorganic hybrid perovskites.

In some optional embodiments, as shown in FIG. 1, a plurality of cell units 20 are arranged side by side in a first direction X, a bus component 40 is arranged on at least one side of the cell unit 20 in a second direction Y, and the plurality of cell units 20 are arranged in parallel with the bus component 40 by a connecting layer 30, the first direction X intersecting with the second direction Y.

It can be seen from the foregoing that the cell unit 20 is arranged extending in the second direction Y, and the bus component 40 may be located only on one side of the cell unit 20 in the second direction Y. Of course, the bus component 40 may include two parts respectively located on two sides of the cell unit 20 in the second direction Y.

In these optional embodiments, the photogenerated carriers in a single cell unit 20 may move to the first connecting line 31 and the second connecting line 32 through the film layer within the cell unit 20, that is, may transfer to the bus component 40, without the need for the photogenerated carriers in the single cell unit 20 to pass through the film layer in other cell units 20, which reduces the overall internal resistance of the solar cell, thereby improving the photoelectric conversion efficiency of the solar cell.

In some optional embodiments, as shown in FIG. 1, the bus component 40 includes a first bus lines 41 and a second bus lines 42. The first bus line 41 and the second bus line 42 are respectively arranged on two sides of the cell unit 20 in the second direction Y. The first connecting lines 31 of the plurality of cell units 20 are connected to the first bus line 41, and the second connecting lines 32 of the plurality of cell units 20 are connected to the second bus line 42.

In the above arrangement, a plurality of cell units 20 are arranged in parallel, which is conducive to improving the uniformity of individual cell units 20, which in turn reduces the possibility of output power loss due to local differentiation of the individual cell units 20, thereby improving the photoelectric conversion efficiency of the solar cell.

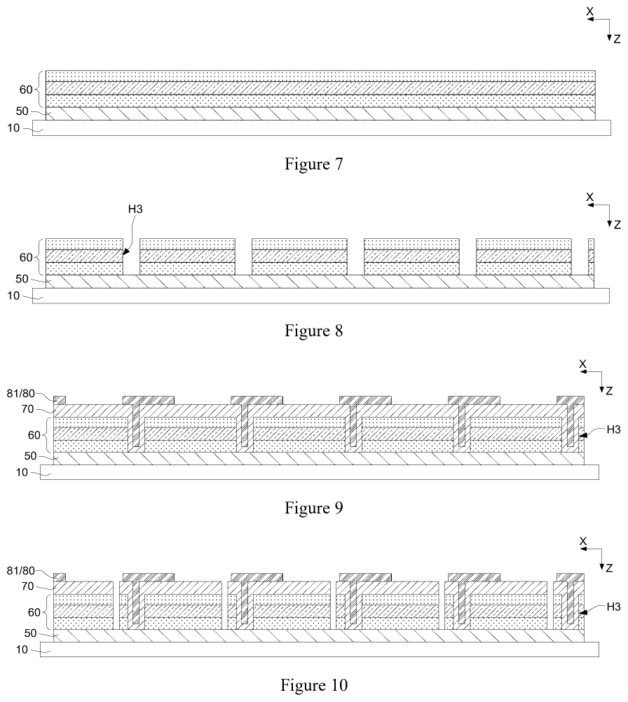

FIG. 6 is a flowchart of a method for manufacturing a solar cell according to an embodiment of the present application. FIGS. 7 to 10 are structural schematic diagrams of a process of a method for manufacturing a solar cell according to an embodiment of the present application.

In one embodiment, referring to FIG. 6, an embodiment of the present application provides a method for manufacturing a solar cell. The method includes the following steps.

At step S100, a first conductive layer 50 and an optical prefabrication layer 60 are sequentially manufactured on a substrate 10.

For example, as shown in FIG. 7, the material of the first conductive layer 50 may include a conductive material. In some examples, the material of the first conductive layer 50 may include a TCO film. The optical prefabrication layer 60 may include a first charge transport material layer, a perovskite material layer, and a second charge transport material layer.

At step S200, the optical prefabrication layer 60 is patterned to expose part of the first conductive layer 50.

Specifically, as shown in FIG. 8, the optical prefabrication layer 60 may be patterned by a process such as laser scribing or mechanical scribing to form a via H3 in the optical prefabrication layer 60.

At step S300, a second conductive layer 70 and a third conductive layer 80 are sequentially formed on a side of the optical prefabrication layer 60 facing away from the first conductive layer 50, and part of the second conductive layer 70 is electrically connected to the first conductive layer 50.

Specifically, as shown in FIG. 9, the second conductive layer 70 may be manufactured by evaporation, physical vapor deposition (PVD) or other processes. During the manufacturing of the second conductive layer 70, part of the second conductive layer is filled in the via H3 to enable part of the second conductive layer 70 to be electrically connected to the first conductive layer 50. The material of the second conductive layer 70 may include ITO, Ag, Cu and another common conductive electrode material. The third conductive layer 80 may be made of conductive ink, conductive polymer material or another material. For example, the material of the third conductive layer 80 may include nanosilver or polyethylene dioxythiophene (PEDOT). Film formation by coating may be used. The third conductive layer 80 is manufactured by printing and patterning, or another process. In some examples, the third conductive layer 80 may be manufactured by inkjet printing, 3D printing, screen printing, transfer printing, etc.

At step S400, the first conductive layer 50, the optical prefabrication layer 60, the second conductive layer 70 and the third conductive layer 80 are all patterned so that the first conductive layer 50, the optical prefabrication layer 60, the second conductive layer 70 and the third conductive layer 80 are separated to form a plurality of cell units 20 spaced apart from each other, where the first conductive layer 50 forms a plurality of first electrode layers 21, the optical prefabrication layer 60 forms a plurality of optical conversion layers 22, the second conductive layer 70 forms a plurality of first sub-portions 231 and a plurality of second sub-portions 232, and the third conductive layer 80 forms a plurality of first connecting lines 31 and a plurality of second connecting lines 32.

For example, the stacked structure formed by the first conductive layer 50, the optical prefabrication layer 60, the second conductive layer 70, and the third conductive layer 80 may be patterned once or multiple times to form a plurality of cell units 20 spaced apart from each other.

In some examples, the stacked structure may be patterned multiple times to form a plurality of cell units 20 spaced apart from each other. For example, as shown in FIG. 10, the optical prefabrication layer 60 and the second conductive layer 70 are patterned once so that the second conductive layer 70 forms the first sub-portion 231 and the second sub-portion 232. As shown in FIG. 2, the first conductive layer 50, the optical prefabrication layer 60, the second conductive layer 70 and the third conductive layer 80 are patterned once so that the first conductive layer 50 forms a plurality of first electrode layers 21, the optical prefabrication layer 60 forms a plurality of optical conversion layers 22, and the third conductive layer 80 forms a plurality of first connecting lines 31 and a plurality of second connecting lines 32. In one embodiment, patterning may be performed using processes such as laser scribing and mechanical scribing.

In some optional embodiments, as shown in FIG. 10, the step of sequentially forming a second conductive layer 70 and a third conductive layer 80 on a side of the optical prefabrication layer 60 facing away from the first conductive layer 50 includes: S310, forming a plurality of conductive portions 81 spaced apart from each other on a side of the second conductive layer 70 facing away from the optical prefabrication layer 60.

Specifically, a third conductive layer 80 is formed on a side of the second conductive layer 70 facing away from the optical prefabrication layer 60, and then the third conductive layer is patterned to form a plurality of conductive portions 81.

The step of patterning the first conductive layer 50, the optical prefabrication layer 60, the second conductive layer 70 and the third conductive layer 80 includes: S410, patterning the conductive portions 81 such that part of each conductive portion 81 forms the first connecting line 31 and the other part forms the second connecting line 32, the first connecting line 31 and the second connecting line 32 connecting different cell units 20.

Specifically, as shown in FIG. 2, each conductive portion 81 is patterned to separate each conductive portion 81 into two parts, one of which forms the first connecting line 31 of one cell unit 20, and the other forms the second connecting line 32 of another cell unit 20.

In some examples, the bus component 40 and the conductive portion 81 are arranged in the same layer, that is, the third conductive portion forms the bus component 40 together during the patterning process. After the first connecting line 31 and the second connecting line 32 are manufactured, the first connecting line 31 and the second connecting line 32 are both connected to the first bus line 41 and the second bus line 42, and then the first connecting line 31 and the second connecting line 32 can be patterned to connect the first connecting line 31 only to the first bus line 41 and connect the second connecting line 32 only to the second bus line 42 so that a plurality of cell units 20 are connected in parallel. In one embodiment, patterning may be performed using processes such as laser scribing and mechanical scribing.

Although the embodiments disclosed in the present application are as described above, the content described is only embodiments used to facilitate the understanding of the present application rather than to limit the present disclosure. The present application pertains may make any modification and variation in the form and details of implementation without departing from the spirit and scope disclosed in the present application, but the scope of protection of the present application shall still be subject to the scope defined by the appended claims.

The above descriptions are merely specific embodiments of the present application. For convenience and brevity of description, for replacement of other connection manners described above, reference may be made to the corresponding processes in the above method embodiments, and details are not repeated herein. It should be understood that the scope of protection of the present application is not limited thereto, any equivalent modification or replacement that can be easily conceived within the scope disclosed in the present application in the art shall fall within the scope of protection of the present application.

What is claimed is:

1. A solar cell, comprising:
a substrate;
a plurality of cell units located on one side of the substrate, each of the cell units comprising a first electrode layer, an optical conversion layer and a second electrode layer which are stacked in sequence, the second electrode layer comprising a first sub-portion and a second sub-portion, the first sub-portion being insulated from the first electrode layer, and the second sub-portion being electrically connected to the first electrode layer;
connecting layers each located on a side of the cell unit facing away from the substrate, each of the connecting layers comprising a first connecting line and a second connecting line, the first connecting line being electrically connected to the first sub-portion, and the second connecting line being electrically connected to the second sub-portion; and
a bus component electrically connected to the connecting layer.

2. The solar cell according to claim 1, wherein the plurality of cell units are arranged side by side in a first direction, and the first connecting line and the second connecting line are arranged at two ends of each of the cell units in the first direction.

3. The solar cell according to claim 2, wherein the first sub-portion and the second sub-portion are spaced apart from each other in the first direction.

4. The solar cell according to claim 1, wherein each of the cell units comprises a first groove running through the second electrode layer.

5. The solar cell according to claim 1, wherein each of the cell units comprises a first groove running through the second electrode layer and at least part of the optical conversion layer.

6. The solar cell according to claim 2, wherein a gap is provided between two adjacent cell units, and the first connecting line of one of the two adjacent cell units and the second connecting line of the other are arranged close to the gap.

7. The solar cell according to claim 1, wherein each of the cell units further comprises a via running through the optical conversion layer, at least part of the second sub-portion being located in the via.

8. The solar cell according to claim 7, wherein the second sub-portion comprises a main body portion and a connecting portion, the main body portion and the first sub-portion being arranged on a same layer, the connecting portion being connected to the first electrode layer through the via, a second groove being formed in a side of the connecting portion facing away from an inner wall of the via, and at least part of the second connecting line being located in the second groove.

9. The solar cell according to claim 8, wherein the second connecting line comprises a covering portion and an extension portion connected to each other, the covering portion covering at least part of a side of the main body portion facing away from the first electrode layer, and the extension portion extending from a side of the covering portion facing the first electrode layer into the second groove.

10. The solar cell according to claim 9, wherein the optical conversion layer comprises a first charge transport layer, a semiconductor layer and a second charge transport layer which are stacked in sequence in a direction away from the substrate, and a projection of the extension portion in the first direction at least partially overlaps with a projection of the semiconductor layer in the first direction.

11. The solar cell according to claim 10, wherein a material of the semiconductor layer comprises one or a combination of crystalline silicon, perovskite, arsenic telluride, copper indium gallium selenide and gallium arsenide.

12. The solar cell according to claim 1, wherein the plurality of cell units are arranged side by side in the first direction, the bus component is arranged on at least one side of the cell units in a second direction, and the plurality of cell units are arranged in parallel with the bus component by the connecting layers, the first direction intersecting with the second direction.

13. The solar cell according to claim 12, wherein the bus component comprises a first bus line and a second bus line which are respectively arranged on two sides of the cell units in the second direction;
wherein the first connecting lines of the plurality of cell units are connected to the first bus line, and the second connecting lines of the plurality of cell units are connected to the second bus line.

14. A method for manufacturing a solar cell, the method comprising:
sequentially forming a first conductive layer and an optical prefabrication layer on the substrate;
patterning the optical prefabrication layer to expose part of the first conductive layer;
sequentially forming a second conductive layer and a third conductive layer on a side of the optical prefabrication layer facing away from the first conductive layer, with part of the second conductive layer being electrically connected to the first conductive layer; and
patterning the first conductive layer, the optical prefabrication layer, the second conductive layer and the third conductive layer so that the first conductive layer, the optical prefabrication layer, the second conductive layer and the third conductive layer are separated to form a plurality of cell units spaced apart from each other, wherein the first conductive layer forms a plurality of first electrode layers, the optical prefabrication layer forms a plurality of optical conversion layers, the second conductive layer forms a plurality of first sub-portions and a plurality of second sub-portions, and the third conductive layer forms a plurality of first connecting lines and a plurality of second connecting lines.

15. The manufacturing method according to claim 14, wherein the step of sequentially forming a second conductive layer and a third conductive layer on a side of the optical prefabrication layer facing away from the first conductive layer comprises:
forming a plurality of conductive portions spaced apart from each other on a side of the second conductive layer facing away from the optical prefabrication layer; and the step of patterning the first conductive layer, the optical prefabrication layer, the second conductive layer and the third conductive layer comprises:
patterning the conductive portions so that part of each of the conductive portions forms the first connecting line and the other part forms the second connecting line, the first connecting line and the second connecting line being connected to different cell units.
